(19) United States
(12) Patent Application Publication
(10) Pub. No.: US 2025/0391494 A1
(43) Pub. Date: Dec. 25, 2025

(54) APPARATUS INCLUDING INTERNAL CAPACITY MEASUREMENT AND ASSOCIATED METHODS

(71) Applicant: Micron Technology, Inc., Boise, ID (US)

(72) Inventor: Sujeet Ayyapureddi, Boise, ID (US)

(21) Appl. No.: 19/244,966

(22) Filed: Jun. 20, 2025

Related U.S. Application Data
(60) Provisional application No. 63/663,625, filed on Jun. 24, 2024.

(51) Int. Cl. G11C 29/00; G11C 29/30

(52) U.S. Cl. CPC G11C 29/88; G11C 29/30; G11C 29/76; G11C 29/787

(57) ABSTRACT

An apparatus including memory systems and related methods for measuring device memory capacity are disclosed herein. The apparatus may include a memory array corresponding to an actual memory capacity that is less than an initial storage capacity. The apparatus may also include a fuse array configured to store unusable memory addresses of the memory array. A logic device of the apparatus coupled to the memory array and the fuse array may be configured to access the unusable memory addresses and communicate to an external device the actual memory capacity of the memory array.

### CROSS-REFERENCE TO RELATED APPLICATION(S)

The present application claims priority to U.S. Provisional Patent Application No. 63/663,625, filed Jun. 24, 2024, the disclosure of which is incorporated herein by reference in its entirety.

### TECHNICAL FIELD

The present technology is directed to apparatuses, such as semiconductor devices including memory and processors, and several embodiments are directed to semiconductor devices that include mechanisms for internal memory capacity measurement.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, reducing power consumption, or reducing manufacturing costs, among other metrics. However, attempts to meet the market demands, such as by reducing the overall device footprint and improving power efficiency, can often introduce challenges in other aspects, such as accounting for circuit defects during manufacturing processes and/or device yield loss.

### BRIEF DESCRIPTION OF THE DRAWINGS

FIG. 1 is a cross-sectional view of a system-in-package device in accordance with embodiments of the technology.

FIG. 2 is a block diagram of a memory device in accordance with embodiments of the technology.

FIG. 3A is a block diagram of a memory device logic in accordance with embodiments of the technology.

FIG. 3B is an illustration of a memory reporting protocol in accordance with embodiments of the technology.

FIG. 3C is an illustration of an example memory reporting sequence in accordance with embodiments of the technology.

FIG. 4 is a flow diagram illustrating a first example method of operating an apparatus in accordance with an embodiment of the present technology.

FIG. 5 is a flow diagram illustrating a second example method of operating an apparatus in accordance with an embodiment of the present technology.

FIG. 6 is a flow diagram illustrating an example method of modifying an apparatus in accordance with an embodiment of the present technology.

FIG. 7 is a block diagram of a system that includes an apparatus configured in accordance with embodiments of the present technology.

### DETAILED DESCRIPTION

As described in greater detail below, the technology disclosed herein relates to an apparatus, such as for memory systems, systems with memory devices, related methods, etc., for measuring device memory capacity. An apparatus (e.g., a memory device, such as an HBM and/or a RAM, and/or a corresponding system) can include an internal storage mechanism (e.g., a fuse array) configured to receive and store memory addresses corresponding to unusable memory regions of the apparatus. The apparatus can also include an internal logic configured to access the recorded memory addresses of the unusable memory regions, thereby determining an actual (e.g., usable and/or non-defective) memory capacity of the apparatus that is available for use by an external device (e.g., an external memory controller). The internal logic can also generate custom page tables for external devices based on the actual memory capacity of the apparatus, such as by excluding memory addresses corresponding to unusable memory regions, thereby improving accessibility of available apparatus memory for the external devices.

Conventional devices are typically configured to downgrade internal memory of the device to a smaller discrete memory capacity (e.g., subset of accessible memory regions of the device) in response to determining defects and/or unusable memory regions. For example, a memory device with an initial target memory capacity (e.g., 24 GB) during manufacture may be downgraded to the next predetermined memory capacity (e.g., 16 GB) when defective memory regions are found after complete manufacture of the device. Such downgrades are often implemented at higher levels of memory groupings, such as channels, banks, etc., thereby eliminating from use larger portions of functioning circuitry that happens to belong in the same group as the defective circuit. In extreme cases, conventional methods often discard the entire memory device itself when downgrading to a smaller discrete memory capacity is not feasible. As such, conventional methods of addressing defects in memory device manufacture often result in significant material (e.g., silicon-based media) and operational (e.g., manufacture cost) waste.

Similarly, external devices (e.g., memory controllers) communicating with a conventional downgraded memory device are often restricted to access only a subset of memory regions that are free of manufacture defects. However, the higher-level memory regions excluded from this restricted subset typically have fully functional memory regions (e.g., discounting minor manufacture defects) that will not be utilized during the lifetime of the memory device. Accordingly, such conventional design often underutilizes the total memory capacity of the memory device that is available for external devices by placing a suboptimal limit on accessible memory regions.

In contrast, the embodiments of the apparatus in accordance with the present technology can include the internal mechanism that stores (e.g., on storage fuses) specific memory addresses or rows corresponding to the unusable memory regions of a memory device. In some embodiments, the internal mechanism can include a memory write circuitry that can receive memory addresses corresponding to unusable memory regions from an external testing device and write the memory addresses onto permanent memory storages (e.g., fuse storage). The apparatus can further include an internal logic that accesses the recorded memory addresses of unusable memory regions and determines an actual memory capacity of the apparatus. Accordingly, the apparatus can provide increased accuracy and lower granularity necessary to pin-point defective circuits, thereby allowing usage of functioning circuits within the high-level groupings. Further, the internal mechanism can increase the storage capacity and yield rates for memories having defective storage circuits.

### Example Environment

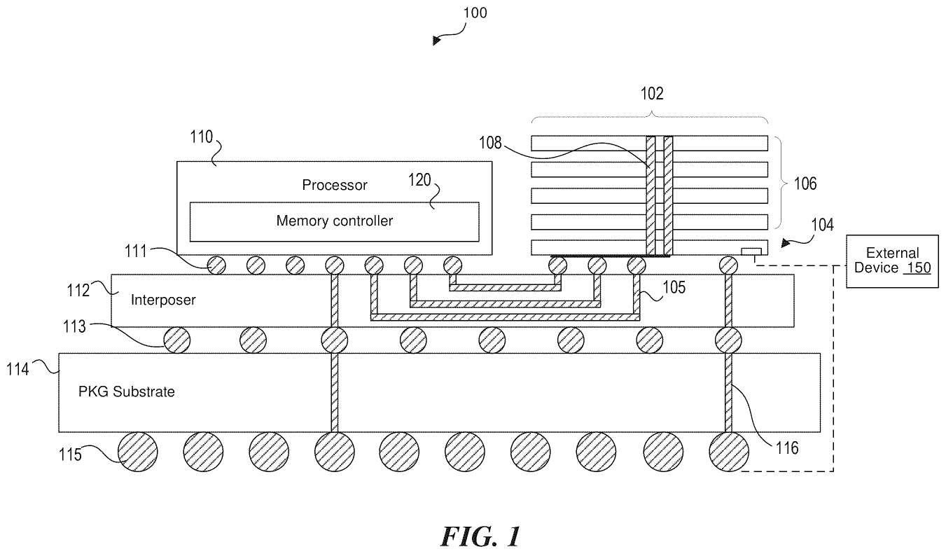

FIG. 1 illustrates a schematic cross-sectional view of a system-in-package (SiP) device 100 (i.e., an example apparatus) in accordance with embodiments of the technology. The SiP 100 can include the memory device 102 and the processor 110, which are packaged together on a package substrate 114 along with an interposer 112. The processor 110 may act as a host device of the SiP 100. The processor 110 may include a memory controller 120 (e.g., a logic device configured to manage to/from the memory device 102) for providing memory operations for storing data to and accessing data from the memory device 102.

In some embodiments, the memory device 102 may be an HBM device that includes an interface die (or logic die) 104 and one or more memory core dies 106 stacked on the interface die 104. The memory device 102 can include one or more through silicon vias (TSVs) 108, which may be used to couple the interface die 104 and the core dies 106. In additional or alternative embodiments, the memory device 102 may include an initial storage capacity (e.g., design memory capacity) targeted during manufacture of the memory device 102. In particular, the initial storage capacity corresponds to a combination of both usable memory regions (e.g., functional memory cells) and unusable memory regions (e.g., non-functional memory cells) of the memory device 102. In some embodiments, the unusable memory regions are associated with defects incurred during manufacture processes of the memory device 102, gradual deterioration of memory cells, or a combination thereof. The memory device 102 may further include an actual storage capacity that is less than the initial storage capacity based on a total memory size corresponding to usable memory regions of the one or more memory core dies 106 of the memory device 102.

The interposer 112 can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. Although only three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and interposer 112 to the interface die 104.

In some embodiments, the direct access bumps 116 (e.g., one or more of the bumps 115) and/or other bumps may be organized into a probe pad (e.g., a set of test connectors). An external tester 150 may be coupled onto the probe pad in order to directly communicate with the memory device 102. In other words, the external tester 150 may send signals to and/or receive signals from the memory device 102 without the signals passing through the processor 110 after the memory device 102 is mounted on the interposer 112. The external tester 150 may be used to test the memory device 102 before it is mounted on the interposer 112 and/or coupled to the processor 110. In some embodiments, the actions performed by the external tester 150 may be performed by the memory controller 120 of the processor 110.

The external tester 150 can function as a host device for the test that interacts with a built-in memory test circuit of the memory device 102 to implement a self-test. The memory test circuit may be used to evaluate and/or identify defective (e.g., unusable) memory regions across one or more core memory dies of the memory device 102. The memory test circuit may then provide to the external tester 150 a set of virtual memory addresses corresponding to the identified defective memory regions along the direct access terminals 116. The interface die 104 may perform, via the memory test circuit, one or more tests on the memory device 102 based on the test instructions and the loaded test patterns and may generate result information. The test results can be monitored during the test to find when failure occurs or read at the end of the test for a pass/fail conclusion.

The test patterns and the instructions can correspond to one or more tests performed on the memory device 102. The test may involve loading a pattern of data into one or more memory cells of the memory device 102 as part of a write operation, retrieving the stored information from the memory cells as part of a read operation, and comparing the written data to the read data. A test may be performed using the memory test circuit of the memory device 102. The tests may be performed using extremely long test patterns with random characteristics, which may require more storage space than is practical in the memory test circuit. Such tests may be performed by directly sending test patterns and instructions through the DA terminals 116.

### Example Circuitry

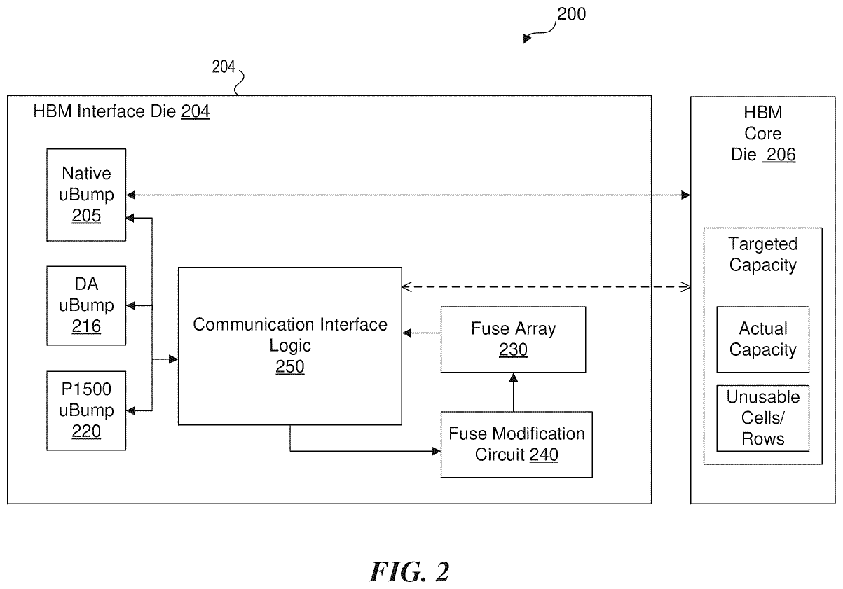

FIG. 2 is a block diagram of a memory device 200 (i.e., an example apparatus, such as the memory device 102 of FIG. 1 or a portion thereof) in accordance with embodiments of the technology. The memory device 200 (e.g., an HBM device) may include an interface die 204 and one or more core dies 206 stacked on top of each other. For clarity, only a single core die 206 is shown in FIG. 2, however it should be understood that multiple core dies 206 may be coupled to the interface die 204 (e.g., there may be 2, 7, or other quantities of core dies 206). In some embodiments, memory cells of each core memory die 206 of the memory device 200 can be grouped into unique channels, banks, blocks, pages, columns, rows, or a combination thereof.

The memory device 200 can include different interface terminals for accessing the core die(s) 206 and/or one or more circuits of the memory. In some embodiments, the different interface terminals can include native micro-bumps (uBumps) 205, DA uBumps 216, and/or test interface uBumps 220. The test interface uBumps 220 may be part of a specific interface protocol, such as the IEEE 1500 interface (also referred to as a P1500 interface). The native uBumps 205 may, in some embodiments, be included in the uBumps 111 of FIG. 1. The native uBumps 205 may be coupled to a processor (e.g., the processor 110 of FIG. 1) via one or more connections (e.g., the channels 105 of FIG. 1). The native uBumps 205 and the connections can enable the processor to access information (via, e.g., read or write operations and the corresponding exchange of information) in the core die(s) 206. For example, the core dies 206 may receive a command (e.g., a read command) along with address information (AWORD), such as such as a row address, column address, a bank address, a die identifier, or the like, that specifies a location for the memory access. The AWORD may also include command information, such as clock signals used for the timing of operations and command identifiers. The accessed information (DWORD), such as the write data or the read data can also be exchanged through the native uBumps 205.

In some embodiments, the interface die 204 may include a serializer configured to process the DWORD between the core dies 206 to the native uBumps 205. For example, the serializer may receive information in parallel along a first number of data lines (e.g., from the core 206), and then provide that information in a serial fashion along a second number of data lines (e.g., to the native uBumps 205). The serializer may be used to multiplex a number of outputs (e.g., from the core 206) to a smaller number of data lines (e.g., to the native uBumps 205).

The memory device 200 can have an initial storage capacity (e.g., intended design memory capacity) targeted during manufacture of the device 200. For example, each core memory die 206 of the memory device 200 can have a targeted memory capacity (e.g., quantity and/or proportion of functional memory array) at start of manufacturing the core memory die 206. As such, the targeted storage capacity for the memory device 200 can be determined as a cumulative sum of the predetermined memory capacities for each core memory die 206 of the memory device 200.

Furthermore, the memory device 200 can have an actual storage capacity less than the targeted storage capacity corresponding to a total functional memory yield after manufacture completion. In particular, the actual storage capacity corresponds to a cumulative memory capacity of the memory device 200 that excludes unusable storage locations, such as defective memory cells or inaccessible memory addresses, that were damaged during manufacture of the device 200. As an illustrative example, the memory device 200 may incur defects to the one or more core memory dies 206 resulting in unusable memory regions (e.g., and corresponding memory addresses) for external devices.

The interface die 204 of the memory device 200 can comprise a fuse array 230, a fuse modification circuit 240, and a communication interface logic 250. The fuse array 230 of the interface die 204 includes an array of fuses or other non-volatile memory cells configured for permanently storing unusable memory addresses of the one or more core memory dies 206. For example, the fuse array 230 can store unusable memory addresses that correspond to memory regions within each of the core memory dies 206. In other words, the fuse array 230 can store the unusable memory address that are unique to each die and independent from (e.g., not grouped with) other core memory dies 206. In some embodiments, the unusable memory addresses stored on the fuse array 230 can be configured to indicate different channels, different banks, different blocks, different pages, different rows, different columns, or a combination thereof across different dies in the one or more core memory dies 206 of the memory device 200.

The fuse array 230 can be communicatively coupled to the fuse modification circuit 240 and the communication interface logic 250. Accordingly, the communication interface logic 250 can be configured to read stored data (e.g., unusable memory addresses) from the fuse array 230 and work with the fuse modification circuit 240 to write data onto the fuse array 230. In additional or alternative embodiments, the fuse array 230 can be configured to store the initial storage capacity intended for the memory device 200.

The fuse modification circuit 240 can be configured to write data onto the fuse array 230. As an example, the fuse modification circuit 240 can receive and store an updated set of unusable memory addresses for the one or more core memory dies 206 onto the fuse array 230. In some embodiments, the fuse modification circuit 240 can be configured to receive the updated set of unusable memory addresses for the one or more core memory dies 206 from an internal memory test circuit of the communication interface logic 250 or an external testing device (e.g., and external test circuit) coupled to the memory device 200. The fuse modification circuit 240 can include a pulse generator or a switchable voltage source configured to set or adjust a memory cell state, such as by setting or tripping a fuse. The fuse modification circuit 240 can adjust the states of the non-volatile or permanent memory cells to represent or store the unusable memory addresses.

The communication interface logic 250 of the interface die 204 can be communicatively coupled to the core memory dies 206, the fuse array 230, and the fuse modification circuit 240 and configured for communicating the actual memory capacity of the memory device 200 to an external device (e.g., an external memory controller, system host, or combination thereof external to the memory device). For example, the communication interface logic 250 can access a set of unusable memory addresses for the core memory dies 206 stored on the fuse array 230. The unusable memory addresses represent physically unusable memory storage locations (e.g., channel, bank, block, page, row, column, etc.) of the one or more core memory dies 206. The communication interface logic 250 can further access the initial storage capacity intended for the memory device 200 from the fuse array 230. In additional or alternative embodiments, the communication interface logic 250 can use the set of unusable memory addresses to determine a set of usable memory addresses for the core memory dies 206.

Based on the set of unusable memory addresses, the set of usable memory addresses, the initial storage capacity (e.g., or a combination thereof), the communication interface logic 250 can compute the actual memory capacity representative of a total functional memory capacity of the memory device 200 available for use by the external device. Accordingly, the communication interface logic 250 can be configured to directly communicate the actual memory capacity to the external device via the native uBumps 205, the DA uBumps 216, and/or the P1500 uBumps 220. In some embodiments, the communication interface logic 250 can also communicate the initial storage capacity (e.g., targeted memory capacity during manufacture) to the external device along with the actual memory capacity.

Additionally or alternatively, the communication interface logic 250 can be configured to communicate the set of unusable memory addresses of the core memory dies 206 instead of the actual memory capacity to the external device. In some embodiments, the communication interface logic 250 can be configured to communicate the set of unusable memory addresses of the core memory dies 206 according to a predetermined reporting sequence or protocol. As an illustrative example, the communication interface logic 250 can obtain (1) a first set of unusable memory addresses that identify a first unusable memory region and (2) a second set of unusable memory addresses corresponding to a second unusable memory region of the memory device 200. Accordingly, the communication interface logic 250 can sequentially report the first set of unusable memory addresses and then the second set of unusable memory addresses according to a predetermined memory reporting protocol described herein. In reporting each set of unusable memory addresses, the communication interface logic 250 can provide a start address and a stop address, a start address and a size (e.g., a number of rows), or a combination thereof for the corresponding locations. In some embodiments, the first set of unusable memory addresses, the second set of unusable memory addresses, or both can include memory addresses for unusable rows of memory cells that are non-adjacent, non-sequential, and/or separated by one or more usable rows of memory cells. The communication interface logic 250 can be configured to identify the unusable locations in one die and then identify the unusable locations in the next die. The communication interface logic 250 may use a predetermined command or indicator, a die indicator, or a continual addressing scheme to differentiate reporting of unusual locations across different dies. Further communication interface logic 250 can be configured to report the unusable locations of the dies according to a predetermined sequence for the dies within the memory device 200.

In additional embodiments, the communication interface logic 250 can be configured to facilitate communications between the external device and the memory device 200, thus enabling the external device to access the memory cells on the core memory dies 206. The communication interface logic 250 may be configured to map or further translate memory addresses provided by the processor 110 and/or the memory controller 120 of FIG. 1 to the usable memory addresses. For example, the communication interface logic 250 can apply a predetermined offset or an equation that maps a linear sequence of addresses to different usable regions within the core dies 206 and bypass the unusable locations. In other words, the memory controller 120 can map the virtual address to a set of physical address that match the actual capacity, and the communication interface logic 250 can further map the set of physical addresses to the usable locations.

As an illustrative example, the communication interface logic 250 can be configured to dynamically derive a page table based on the actual memory capacity, and/or the set of unusable memory addresses, of the memory device 200 for facilitating memory operations commanded by the external device. In particular, the communication interface logic 250 can build a page table that accounts for the set of unusable memory addresses such that the page table is configured to translate (1) logical addresses (e.g., virtual memory addresses) used by the external device or (2) an intermediate set of physical addresses used by the memory controller 120 to physical addresses corresponding to usable storage locations within the memory device 200. Accordingly, the communication interface logic 250 can build the page table to exclude translations (e.g., accessible memory operations) of logical addresses that correspond to unusable physical memory addresses of the memory device 200. The communication interface logic 250 can be configured to communicate the derived page table to the external device along with the actual memory capacity, the set of unusable memory addresses, or any combination thereof. In other embodiments, the memory controller 120 can locally generate the page tables with blocks of separated physical addresses to avoid the unusable memory addresses received from the communication interface logic 250.

In addition to the operational configurations (e.g., native operational mode) associated with the native uBumps 205, the communication interface logic 250 can be configured to operate in a memory test mode. In some embodiments, the communication interface logic 250 can include an internal test circuit (e.g., a Built-In Self-Test (BIST) circuit). In other embodiment, the communication interface logic 250 can be physically separate from and communicatively coupled to the internal text circuit.

In test mode, the internal test circuit can determine one or more characteristics (e.g., signal responses, manufacturing defects, failure or error related aspects, or other aspects of the circuit) of the memory device 200. The internal test circuit, either working alone or with the external tester 150, can implement a test sequence that writes a predetermined set of data to the memory cells of the core die 206, reads back the stored data, and then compare the read data to the predetermined set. The internal test circuit, the external tester 150, or a combination thereof can use the comparison to determine the unusable locations (e.g., locations that fail to accurately store or read-back the data).

The communication interface logic 250 can obtain the unusable locations resulting from the testing sequence, such as by receiving the unusable locations from the internal test circuit and/or the external tester 150. In completing and logging the test results, the communication interface logic 250 can operate the fuse modification circuit 240 to permanently store the unusable locations (e.g., unusable memory channels, banks, blocks, pages, rows, columns, etc.) in the fuse array 230.

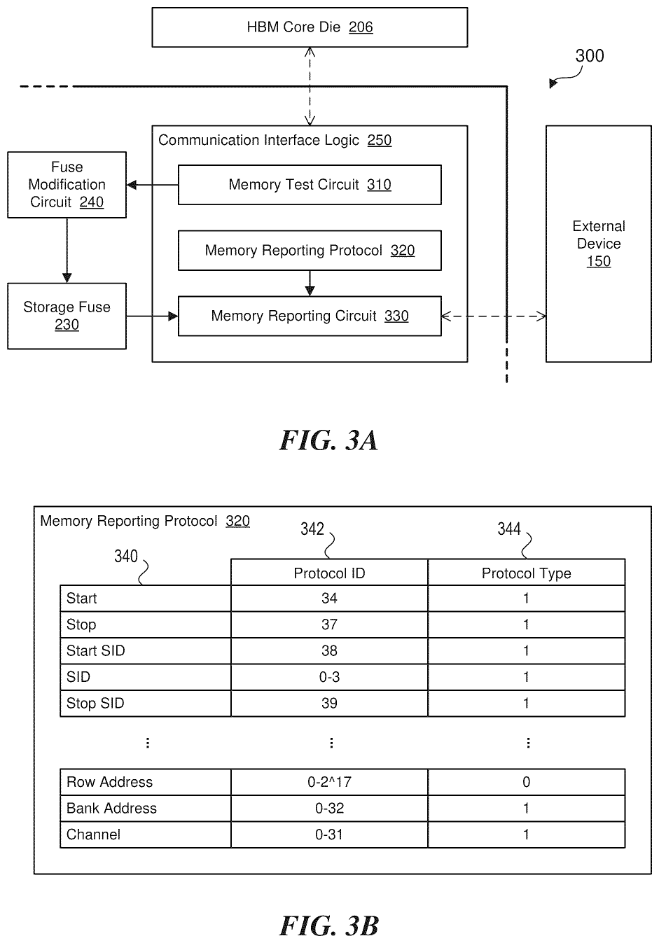

FIG. 3A is a block diagram of a memory device logic 300 (i.e., an example logic circuit, such as the communication interface logic 250 of FIG. 2 or a portion thereof) in accordance with embodiments of the technology. The memory device logic 300 may include a memory test circuit 310 and a memory reporting circuit 330 configured to operate according to a memory reporting protocol 320.

The memory test circuit 310 can be coupled to the one or more core memory dies 206 of the memory device 200 and the fuse modification circuit 240. The memory test circuit 310 can be configured to identify the unusable memory addresses of the memory device 200. For example, the memory test circuit 310 can perform a self-test (e.g., write-read validation) to identify a current set of unusable memory regions (e.g., physical memory/row addresses) of the memory device 200 across the one or more core memory dies 206. The memory test circuit 310 can be further configured to supply the memory addresses corresponding to the current set of unusable memory regions to the fuse modification circuit 240 to be stored on the fuse array 230. In additional or alternative embodiments, the operations of the memory test circuit 310 can be coordinated with the external device 150 (e.g., an external tester) communicatively coupled to the interface die 204 of the memory device 200.

The memory reporting circuit 330 can be coupled to an external device 150, the fuse array 230, and the memory reporting protocol 320 and be configured to report the actual memory capacity of the memory device 200 to the processor 110 of FIG. 1 and/or the memory controller 120 of FIG. 1 according to a die reporting sequence structure. As an example, the memory reporting circuit 330 can translate an identified set of unusable memory addresses into a memory reporting sequence 350 for the memory controller 120 based on the memory reporting protocol 320. The memory reporting sequence 350 provides sequential instructions for the memory controller 120 to navigate the core memory dies 206 of the memory device 200 and avoid unusable regions. In some embodiments, the memory reporting protocol 320 can be a predetermined set of rules for generating memory navigation instructions comprising the memory reporting sequence 350. As an illustrative example, the memory reporting protocol 320 can associate each core memory die 206 of the memory device 200 to a specified report order such that memory navigation instructions corresponding to a core memory die 206 with an earlier report order are added earlier in the memory reporting sequence 350.

FIG. 3B is an illustration of a memory reporting protocol 320 in accordance with embodiments of the technology. The memory reporting protocol 320 may be communicatively coupled to a memory reporting circuit 330. In some embodiments, the memory reporting protocol 320 may be embedded within the communication interface logic 250 of the interface die 204.

The memory reporting protocol 320 may correspond to a predetermined set of rules for generating sequential memory navigation instructions for an external device 150 to access select memory regions of a memory device 200. As described herein, the memory reporting circuit 330 can generate a memory reporting sequence 350 based on the predetermined set of rules of the memory reporting protocol 320 to sequentially report unusable memory addresses of the memory device 200.

In some embodiments, the predetermined set of rules of the memory reporting protocol 320 can be configured as a mapping of a specified memory navigation instruction 340 to a protocol identification code 342 (e.g., specified instruction, memory address) and protocol command type 344 (e.g., memory navigation, memory read and/or write), as shown in FIG. 3B. Memory navigation instructions 340 correspond to unique operational steps (e.g., starting navigation, entering specified memory channel, skipping select memory rows, etc.) to be used by the processor 110 and/or the memory controller 120 to traverse the memory device 200. In some embodiments, a memory navigation instruction 340 can be represented through a fixed-length bit array such that a first portion of the bit array (e.g., most significant bits) corresponds to the protocol identification code 342 and a second portion of the bit array (e.g., least significant bit) corresponds to the protocol command type 344. Accordingly, a memory reporting sequence 350 can comprise a compact sequence of the fixed-length bit arrays each corresponding to a memory navigation instruction 340.

FIG. 3C is an illustration of an example memory reporting sequence in accordance with embodiments of the technology. As depicted, the example memory reporting sequence 350 includes an instruction sequence 352 corresponding to an ordered list of memory navigation instructions 340 for an external device 150 to navigate the memory device 200. For clarity, an instruction summary 354 for each memory navigation instruction 340 is shown in FIG. 3C, however it should be understood that generation of memory reporting sequences 350 for use by the processor 110 and/or the memory controller 120 may exclude such element.

In some embodiments, the instruction sequence 352 of the memory reporting sequence 350 can be ordered to report step-by-step, such as from a higher-level memory region to a lower-level memory region, via each subsequent memory navigation instruction 340. As an illustrative example, the instruction sequence 352 depicted in FIG. 3C guides the processor 110 and/or the memory controller 120 to access a higher-level memory location (e.g., “Pseudo-Channel 0”) at instruction 360 to a lower-level memory location (e.g., “Bank 0”) at instruction 362. In other embodiments, the instruction sequence 352 can include skip instructions 364 to inform the external tester 150 of inaccessible memory regions (e.g., defective and/or non-functional memory location) at specified memory addresses.

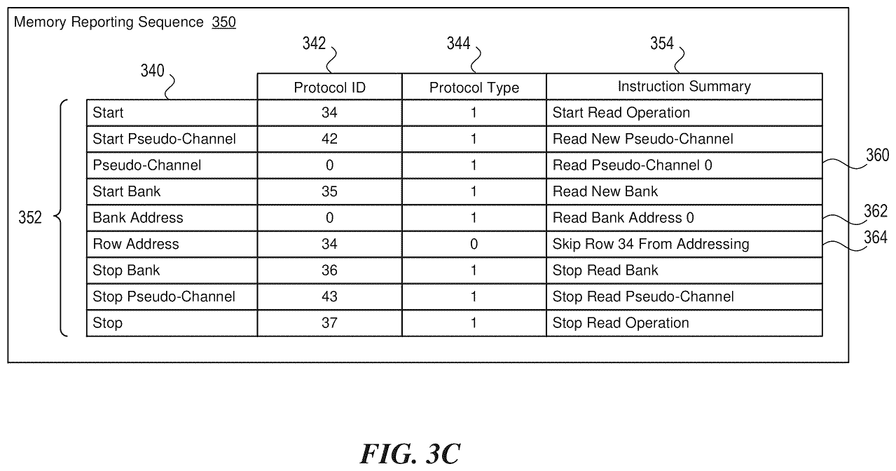

FIG. 4 is a flow diagram illustrating a first example method of operating an apparatus (e.g., the SiP 100 of FIG. 1, the memory device 102 of FIG. 1, the memory device 200 of FIG. 2, the memory device logic 300 of FIG. 3A, a portion thereof, or a combination thereof) in accordance with an embodiment of the present technology. The method 400 can include determining/establishing an available memory capacity of the apparatus for communicatively coupled devices (e.g., the processor 110 of FIG. 1, the memory controller 120 of FIG. 1, or the like).

At block 402, the apparatus can retrieve an initial storage capacity (e.g., design functional memory size) targeted during manufacturing of a memory array of the apparatus. For example, the apparatus can configure a logic circuit (e.g., an interface circuit) retrieve an initial storage capacity for a set of circuits of the apparatus representative of a combined storage capacity between a usable portion (e.g., functional memory) and an unusable portion. In some embodiments, the set of circuits of the apparatus can include memory cells that are located across one or more core memory dies. As an illustrative example, the apparatus can retrieve the initial storage capacity of a high bandwidth memory (HBM) device of the apparatus that can include two or more core dies and an interface die stacked on top of each other.

At block 404, the apparatus can determine one or more unusable regions of the memory array (e.g., storage locations damaged during manufacturing). For example, the apparatus can retrieve one or more location identifiers (e.g., physical memory addresses) that correspond to the unusable portion of the set of circuits for the memory array. In some embodiments, the apparatus can retrieve the one or more location identifiers from a non-volatile memory coupled to the apparatus configured to store the location identifiers for the unusable memory regions of the memory array.

As an illustrative example, at block 412, the apparatus can use the logic circuit (e.g., interface circuit) to retrieve unusable memory addresses from a fuse array. In some embodiments, the apparatus can use one or more logic devices (e.g., an interface circuit located on an interfacing die) coupled to the fuse array to report the stored unusable memory addresses of the memory array.

At block 406, the apparatus can compute an actual memory capacity (e.g., available functional memory) that may be less than the initial storage capacity of the memory array. For example, the apparatus can determine usable (e.g., functional) memory regions of the memory array based on the initial storage capacity and the retrieved unusable memory addresses. As such, the apparatus can calculate the actual memory capacity of the memory array based on the determined usable memory regions.

At block 408, the apparatus can communicate the actual memory capacity of the memory array, or a representation thereof, to an external device (e.g., a memory controller, a system host, or a combination thereof external to the apparatus). For example, at block 414, the apparatus can operate the one or more logic devices (e.g., interface circuit) to directly communicate to the external controller the actual memory capacity instead of the initial storage capacity for the memory array. In some embodiments, the apparatus can directly communicate the initial storage capacity along with the actual memory capacity to the external device (e.g., the processor, the memory controller, or the like).

The apparatus can further operate the one or more logic devices to facilitate communications between the external device and the memory array, such that the apparatus enables the external device to access functional memory cells (e.g., on two or more core dies) of the memory array (e.g., outside of unusable memory regions). For example, at block 416, the apparatus can generate a memory reporting sequence for enabling the external device to identify non-functional memory regions of the memory array. In particular, the apparatus can create a sequence of memory report instructions representative of a structured method for identifying unusable memory addresses during traversal of two or more memory dies of the memory array.

In some embodiments, the apparatus can generate memory report instructions for the memory reporting sequence based on a predetermined protocol for reporting unusable memory addresses. As an illustrative example, the apparatus can generate memory report instructions for a first core die of the memory array having one or more first unusable regions and a second core die of the memory array having one or more second unusable regions based on a first set of unusable addresses corresponding to the first unusable region and a second set of unusable addresses corresponding to the second unusable region, respectively. Using the first and the second sets of unusable addresses, the apparatus can operate the one or more logic devices to sequentially report the first set of unusable addresses and then the second set of unusable addresses according to the predetermined protocol for reporting the unusable memory addresses.

In additional or alternative embodiments, the first set of unusable addresses, the second set of unusable addresses, or both include addresses for unusable rows of memory cells that are non-adjacent and separated by one or more usable rows of memory cells. In other embodiments, the apparatus can generate each memory report instruction by combining a protocol identifier (e.g., a code) and/or a protocol instruction type based on an unusable memory address of the memory array. The apparatus can further configure the sequence of the memory report instructions to specify different channels, different banks, different blocks, different pages, different rows, or a combination thereof for the unusable memory addresses across different dies in the memory array.

At block 418, the apparatus can configure the one or more logic devices to indirectly communicate to the external device the actual capacity based on providing the unusable memory addresses of the memory array. For example, the apparatus can configure the interface circuit to communicate the memory reporting sequence, corresponding to unusable memory addresses, to the external device.

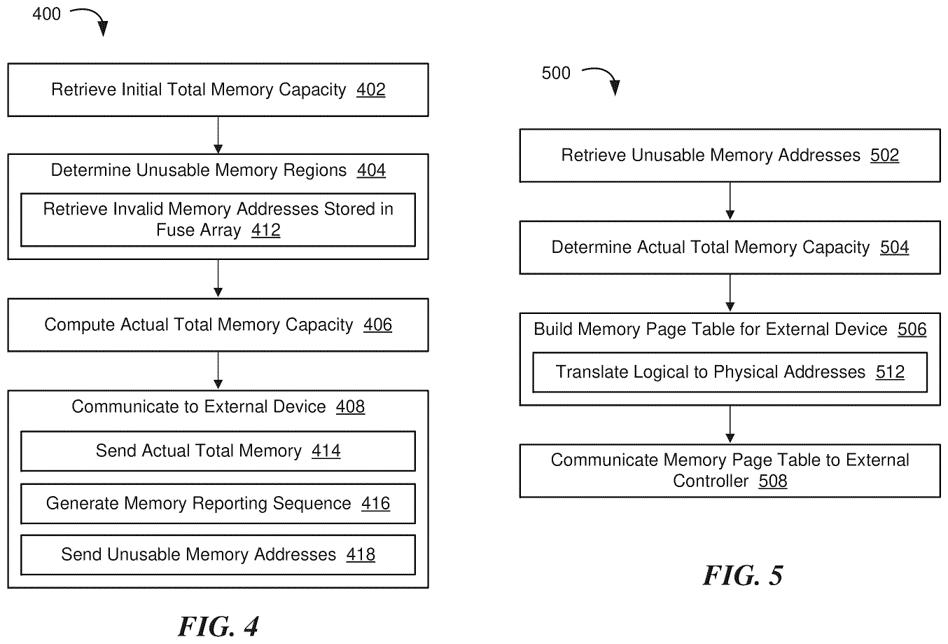

FIG. 5 is a flow diagram illustrating a second example method of operating an apparatus (e.g., the SiP 100 of FIG. 1, the memory device 102 of FIG. 1, the memory device 200 of FIG. 2, the memory device logic 300 of FIG. 3A, a portion thereof, or a combination thereof) in accordance with an embodiment of the present technology. The method 500 can include managing access to usable memory locations, such as by generating a memory page table. In some embodiments, the steps of method 500 can be implemented using a memory controller coupled to the apparatus. In additional or alternative embodiments, the apparatus can implement the method 500.

At block 502, the apparatus can receive a set of unusable memory addresses for a memory device (e.g., HBM device) representative of unusable storage locations within the memory device. For example, the apparatus can operate a logic circuit to obtain the set of unusable memory addresses stored on a non-volatile memory (e.g., fuse array) coupled to the apparatus as discussed herein with respect to block 412 of method 400.

At block 504, the apparatus can determine an actual memory capacity of the memory device. For example, the apparatus can operate the logic circuit to compute an actual memory capacity based on the retrieved set of unusable memory addresses as discussed herein with respect to block 406 of method 400. In some embodiments, the apparatus can determine the actual memory capacity of the memory device as a stored measure of the memory device.

At block 506, the apparatus can dynamically derive a page table for the memory device based on the actual memory capacity and/or the unusable memory addresses for facilitating memory operations commanded by an external device (e.g., the processor, the memory controller, or the like within or external to the SiP). As an illustrative example, at block 512, the apparatus can build a page table that accounts for the set of unusable addresses of the memory devices such that the page table is configured to translate logical addresses (e.g., virtual memory addresses) used by the external device to physical addresses indicating usable storage locations within the memory device. The apparatus can derive the page table at the memory controller, the communication interface logic, or a combination thereof.

At block 508, the apparatus can communicate the memory page table to the external device. For example, the apparatus can configure a communication interface to communicate the derived page table for the memory device to the external device. In some embodiments, the apparatus can also send the actual memory capacity of the memory device to the external device along with the derived page table. In additional or alternative embodiments, the apparatus can send the retrieved set of unusable memory addresses (e.g., virtual memory addresses) to the external device along with the derived page table.

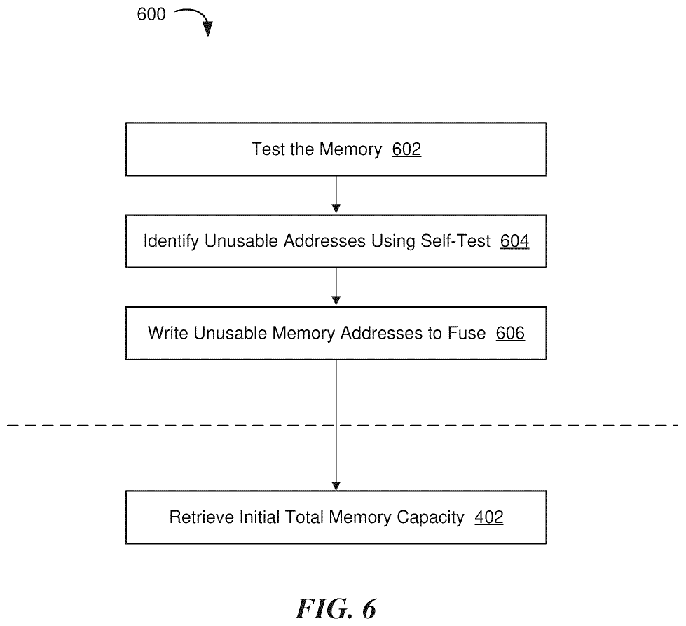

FIG. 6 is a flow diagram illustrating an example method of modifying an apparatus (e.g., the SiP 100 of FIG. 1, the memory device 102 of FIG. 1, the memory device 200 of FIG. 2, the memory device logic 300 of FIG. 3A, a portion thereof, or a combination thereof) in accordance with an embodiment of the present technology. The method 600 can include a memory test circuit for updating unusable memory addresses for a memory device (e.g., HBM device) stored on a non-volatile memory of the apparatus.

At block 602, the apparatus can test the memory, such as the core memory dies within the HBM. For example, the apparatus can operate the internal test circuit (e.g., BIST) to implement a self-test as described above. Accordingly, the apparatus can store a predetermined data pattern onto the core dies and read the data back.

At block 604, the apparatus can identify a current set of unusable memory addresses of the memory device. For example, the apparatus can operate a memory test circuit (e.g., a logic circuit) coupled to the apparatus to perform a comparison portion of the self-test. In some embodiments, the memory test circuit can identify a current set of unusable memory addresses that read back data different from the written data pattern. In additional or alternative embodiments, the apparatus can be communicatively coupled to an external testing device for performing the self-test and receive the current set of unusable memory addresses from the external tester.

At block 606, the apparatus can write the current set of unusable memory addresses of the memory device to the non-volatile memory. For example, the apparatus can operate the fuse modification circuit to write the unusable memory addresses onto the non-volatile memory, such as by tripping fuses to store the unusable addresses. In additional or alternative embodiments, the current set of unusable memory addresses stored on the non-volatile memory can be retrieved by one or more logic circuits of the apparatus as discussed herein with respect to block 402 of method 400.

In some embodiments, the apparatus can leverage the method 500 to update the non-volatile memory during deployed operation. For example, the apparatus can identify memory addresses that become defective after the manufacturing and initial testing, such as when the error rates associated with the memory location exceeds a threshold, when a read voltage level trim is exhausted, or the like. When such triggering conditions are detected, the apparatus can use the operations of blocks 604 and 606 to add to the unusable memory addresses in the non-volatile memory.

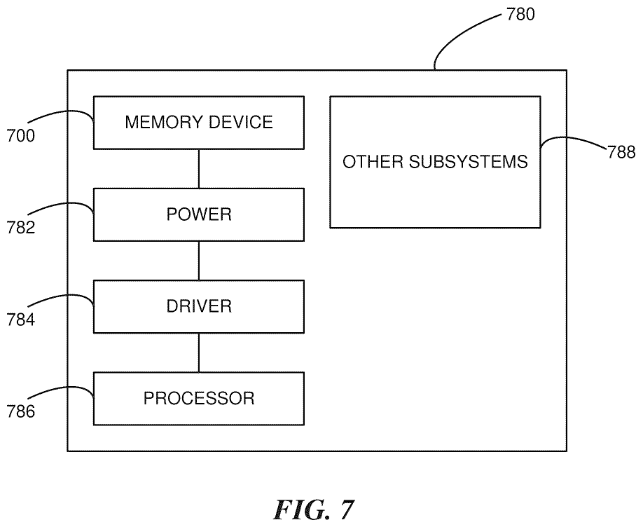

FIG. 7 is a block diagram of a system that includes an apparatus in accordance with embodiments of the present technology. Any one of the foregoing apparatuses (e.g., memory devices) described above with reference to FIGS. 1-6 can be incorporated into or implemented in memory (e.g., a memory device 700) or any of a myriad of larger and/or more complex systems, a representative example of which is system 780 shown schematically in FIG. 7. The system 780 can include the memory device 700, a power source 782, a driver 784, a processor 786, and/or other subsystems or components 788. The memory device 700 can include features generally similar to those of the apparatus described above with reference to FIGS. 1-6 and can therefore include various features for performing a direct read request from a host device. The resulting system 780 can perform any of a wide variety of functions, such as memory storage, data processing, and/or other suitable functions. Accordingly, representative systems 780 can include, without limitation, hand-held devices (e.g., mobile phones, tablets, digital readers, and digital audio players), computers, vehicles, appliances and other products. Components of the system 780 may be housed in a single unit or distributed over multiple, interconnected units (e.g., through a communications network). The components of the system 780 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of HBM and DRAM devices. Apparatuses configured in accordance with other embodiments of the present technology, however, can include other types of suitable storage media in addition to or in lieu of HBM and/or DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-7.

What is claimed is:

1. A memory device, comprising:
a memory array having an initial storage capacity targeted during manufacturing,
wherein the memory array includes unusable memory regions corresponding to unusable memory addresses,
wherein the unusable memory regions represent defective storage locations, and
wherein the memory array corresponds to an actual capacity that is less than the initial storage capacity;
a fuse array coupled to the memory array and including fuses configured to permanently store the unusable memory addresses; and
one or more logic devices coupled to the fuse array and configured to:
access the unusable memory addresses from the fuse array; and
communicate to an external device the actual capacity or a representation thereof instead of the initial capacity for the memory array based on the unusable memory addresses.

2. The memory device of claim 1, wherein the one or more logic devices are configured to:
compute the actual capacity based on the initial capacity, the unusable memory regions, or usable memory regions, or a combination thereof; and
directly communicate the actual capacity along with or instead of the initial capacity to the external device.

3. The memory device of claim 1, wherein the one or more logic devices are configured to indirectly communicate the actual capacity based on communicating the unusable memory addresses to the external device.

4. The memory device of claim 1, wherein:
the memory device comprises a high bandwidth memory (HBM) device that includes (1) an interface die and (2) two or more core dies stacked over the interface die, wherein:
the memory array is implemented through memory cells on the two or more core dies; and
the interface die is configured to facilitate communications with the external device to access to the memory cells on the two or more core dies, wherein the interface die includes the one or more logic devices.

5. The memory device of claim 4, wherein:
the two or more core dies correspond to a die reporting sequence;
the unusable memory addresses correspond to regions that are independent across the two or more core dies; and
the one or more logic devices are configured to send the unusable memory addresses according to the die reporting sequence.

6. The memory device of claim 5, wherein:
the each die in the two or more core dies has the memory cells grouped into channels, banks, blocks, pages, or a combination thereof; and
the unusable memory addresses configurable to selectively indicate different channels, different banks, different blocks, different pages, or a combination thereof across different dies in the two or more core dies.

7. The memory device of claim 5, wherein:
the each die in the two or more core dies has the memory cells grouped into rows; and
the unusable memory addresses are configurable to selectively indicate different rows across different dies in the two or more core dies.

8. The memory device of claim 4, wherein:
the two or more core dies include (1) a first core die having a first unusable region and (2) a second core die having a second unusable region;
the unusable memory addresses include (1) a first set of unusable addresses corresponding to the first unusable region and (2) a second set of unusable addresses corresponding to the second unusable region; and
the one or more logic devices are configured to sequentially report the first set of unusable addresses and then the second set of unusable addresses according to a predetermined protocol.

9. The memory device of claim 8, wherein the first set of unusable addresses, the second set of unusable addresses, or both include non-sequential and/or non-adjacent addresses for unusable rows of memory cells that are separated by one or more usable rows of memory cells.

10. The memory device of claim 1, further comprising;
a memory controller configured to:
receive the actual capacity or the corresponding representation thereof;
dynamically derive a page table based on the actual capacity for facilitating memory operations commanded by the external device; and
facilitate access to the memory array, outside of the unusable memory regions, for the external device.

11. The memory device of claim 1, further comprising:
a fuse modification circuit coupled to the fuse array and configured to:
receive the unusable memory addresses; and
write the unusable memory addresses onto the fuse array.

12. The memory device of claim 11, wherein:
the one or more logic devices are configured to receive the unusable memory addresses from an external tester, wherein the received unusable memory addresses represent results of a self-test of the memory array using the external tester; and
the fuse modification circuit is configured to write to the fuse array according to the received unusable memory addresses.

13. The memory device of claim 11, further comprising:
a memory test circuit coupled to the memory array and the fuse modification circuit, the memory test circuit configured to:
identify the unusable memory regions through a self-test; and
provide to the fuse modification circuit the unusable memory addresses corresponding to the unusable memory regions.

14. A memory controller, comprising:
a communication interface configured to communicate with (1) a memory device and (2) a host device; and
a logic circuit coupled to the communication interface and configured to:
obtain a set of unusable addresses from the memory device, wherein the set of unusable addresses represent unusable physical storage locations within the memory device;
receive command and corresponding logical addresses from the host device for accessing the memory device;
translate the logical addresses to physical addresses using the set of unusable addresses; and
providing the translated physical addresses to the memory device for facilitating the commands for the host device.

15. The memory controller of claim 14, wherein the logic circuit is further configured to:
obtain an actual capacity of the memory device, wherein the actual capacity of the memory device accounts for the set of unusable addresses; and
send to the host device, the actual capacity, the set of unusable addresses, or a combination thereof.

16. An apparatus, comprising:
a set of circuits having an initial capacity and an actual capacity, wherein the actual capacity represents a usable portion of the set of circuits and the initial capacity represents the usable portion along with an unusable portion that has been identified to be non-functional;
a non-volatile memory coupled to the set of circuits and configured to permanently store one or more location identifiers for the unusable portion of the set of circuits; and
one or more logic circuits coupled to a fuse array and configured to report the one or more location identifiers for providing access to the actual capacity of the set of circuits.

17. The apparatus of claim 16, wherein the set of circuits are memory cells that are located across one or more dies.

18. The apparatus of claim 17, wherein:
the one or more dies are core memory dies; and
the one or more logic circuits is an interface logic circuit located on an interfacing die stacked with the one or more core memory dies.

19. The apparatus of claim 18, further comprising:
a memory controller communicatively coupled to the interface logic circuit and configured to exclude the unusable portion from memory operations.

20. The apparatus of claim 19, further comprising:
at least one processor communicatively coupled to the memory controller and providing the memory operations for storing data to and accessing data from the one or more core memory dies.
